(19) United States
(12) Patent Application Publication
(10) Pub. No.: US 2011/0156167 A1
(43) Pub. Date: Jun. 30, 2011

(54) Methods for Consumption of Timing Margin to Reduce Power Utilization in Integrated Circuitry and Device Implementing the Same

(75) Inventor: Stephen Kornachuk, San Jose, CA (US)

(73) Assignee: Tela Innovations, Inc., Los Gatos, CA (US)

(21) Appl. No.: 12/981,151

(22) Filed: Dec. 29, 2010

Related U.S. Application Data
(60) Provisional application No. 61/291,212, filed on Dec. 30, 2009.

(51) Int. Cl. H01L 27/085; G06F 17/50

(52) U.S. Cl. 257/392; 716/104; 257/E27.059

(57) ABSTRACT

A circuit is defined to operate in accordance with a common control signal. The circuit includes a plurality of transistors that have respective timing margins relative to the common control signal. Some of the plurality of transistors are defined differently from another of the plurality of transistors with regard to either transistor channel width, transistor channel length, transistor threshold voltage, or a combination thereof. The different definition of any given one of the plurality of transistors causes a reduction of either transistor power consumption, transistor current leakage, or a combination thereof, in exchange for a corresponding reduction in timing margin while maintaining a positive timing margin.

### CLAIM OF PRIORITY

This application claims priority under 35 U.S.C. 119(e) to U.S. Provisional Patent Application No. 61/291,212, filed Dec. 30, 2009, entitled “Methods for Consumption of Timing Margin to Reduce Power Utilization in Integrated Circuitry and Implementation of the Same,” the disclosure of which is incorporated herein by reference in its entirety.

### BACKGROUND

As electronic devices continue to progress toward smaller, more portable profiles, with increased processing capability, power utilization continues to be an active area of design innovation. Many circuits in modern electronic devices are quite complex and often require designers to make simplifying and conservative assumptions regarding circuit performance in order to satisfy design cost and schedule requirements. As a result, many circuits in modern electronic devices include areas where more sophisticated design methods and technologies may be applied to improve performance, particularly with regard to power utilization. However, development of these more sophisticated design methods and technologies requires innovation to ensure continued satisfaction of design cost and schedule requirements.

### SUMMARY

In one embodiment, a semiconductor device is disclosed to include a circuit defined to operate in accordance with a common control signal. The circuit includes a plurality of transistors that have respective timing margins relative to the common control signal. Some of the plurality of transistors are differentiated from another of the plurality of transistors with regard to either transistor channel width, transistor channel length, transistor threshold voltage, or a combination thereof. The differentiation of any given one of the plurality of transistors is defined to reduce either transistor power consumption, transistor current leakage, or a combination thereof, in exchange for a correspondingly reduced timing margin that remains positive.

In another embodiment, a method is disclosed for consumption of timing margin in an integrated circuit for reduce power utilization. The method includes identifying a circuit defined to operate in accordance with a common control signal. A plurality of transistors are identified within the circuit that have respective timing margins relative to the common control signal. The respective timing margins of the plurality of transistors are determined. The method also includes defining some of the plurality of transistors differently from another of the plurality of transistors with regard to either transistor channel width, transistor channel length, transistor threshold voltage, or a combination thereof. The different definition of any given one of the plurality of transistors causes a reduction of either transistor power consumption, transistor current leakage, or a combination thereof, in exchange for a corresponding reduction in timing margin while maintaining a positive timing margin.

Other aspects and advantages of the invention will become more apparent from the following detailed description, taken in conjunction with the accompanying drawings, illustrating by way of example the present invention.

### BRIEF DESCRIPTION OF THE DRAWINGS

FIG. 1 shows an electronic device architecture in which a number of interrelated circuits are wired to a common control signal source, in accordance with one embodiment of the present invention;

FIG. 2 shows a chart of local circuit characterization indicating whether or not bias candidate transistors of a local circuit should be modified, i.e., should be biased slower, in accordance with one embodiment of the present invention;

FIG. 3 shows a diagram of a transistor, in accordance with one embodiment of the present invention;

FIG. 4 shows a flowchart of a method for consumption of timing margin to reduce power utilization in an integrated circuit, in accordance with one embodiment of the present invention;

FIG. 5 shows a memory circuit architecture, in accordance with one embodiment of the present invention; and

FIG. 6 shows a chart of local circuit characterization in memory indicating whether or not bias candidate transistors of a local circuit in the data interface of the memory should be biased slower, in accordance with one embodiment of the present invention.

### DETAILED DESCRIPTION

In the following description, numerous specific details are set forth in order to provide a thorough understanding of the present invention. It will be apparent, however, to one skilled in the art that the present invention may be practiced without some or all of these specific details. In other instances, well known process operations have not been described in detail in order not to unnecessarily obscure the present invention.

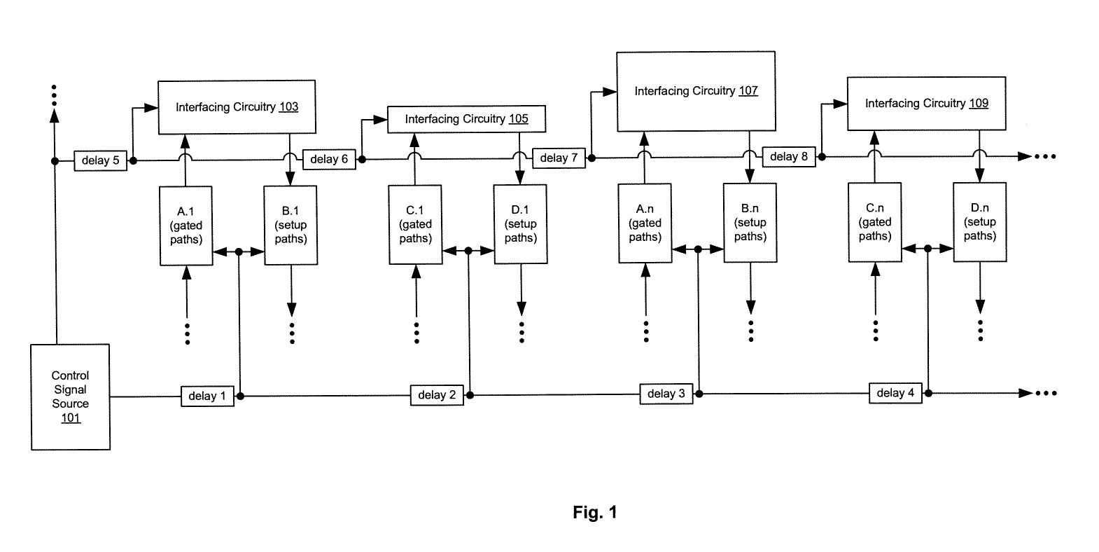

FIG. 1 shows an electronic device architecture in which a number of interrelated circuits are wired to a common control signal source 101, in accordance with one embodiment of the present invention. A number of local circuits (A.1 through A.n, B.1 through B.n, C.1 through C.n, D.1 through D.n) are connected to receive a control signal from the common control signal source 101. The local circuits may include different types of local circuits and may include either gated paths or setup paths.

A gated path is an electrical signal path within a local circuit that is gated, i.e., operated, by transistors having respective control inputs connected to receive the control signal transmitted from the common control signal source 101. Electrical signal transitions in the gated path are initiated by the arrival of an electrical signal transition at the respective control inputs of the transistors in the gated path. Also, a gated path may include a number of transistors that drive an electrical signal to an interfacing circuit to which the local circuit is connected. A critical gated path of a local circuit is a particular gated path within the local circuit that has a lowest amount of timing margin. The timing margin of a given gated path is measured between a moment of arrival at the given gated path of the control signal from the common control signal source 101, and a moment at which electrical signal transitions in the gated path must be initiated to ensure timely completion of those electrical signal transitions for proper operation of circuitry that interfaces with the given gated path.

A setup path is an electrical signal path within a local circuit that includes transistors which together hold one or more electrical signal states that must respectively resolve to desired electrical signal states prior to arrival of the control signal, transmitted from the common control signal source 101, at one or more controlling transistors. Upon arrival of the control signal, the one or more controlling transistors will activate to release the one or more electrical signal states held by the transistors within the setup path. An interfacing circuit to which the local circuit is connected may drive one or more electrical signals into the setup path to resolve the one or more electrical signal states within the setup path. A critical setup path of a local circuit is a particular setup path within the local circuit that has a lowest amount of timing margin. The timing margin of a given setup path is measured between a moment at which electrical signals within the given setup path resolve to the desired electrical signal states, and a moment of arrival at the given setup path of the control signal from the common control signal source 101.

The example electronic device architecture of FIG. 1 shows four different types of locals circuits. Specifically, local circuits A.1 through A.n are of the same type and include gated paths. Local circuits B.1 through B.n are of the same type and include setup paths. Local circuits C.1 through C.n are of the same type and include gated paths. Local circuits D.1 through D.n are of the same type and include setup paths. Local circuits A.1 and BA are electrically connected to interfacing circuitry 103. Local circuits CA and D.1 are electrically connected to interfacing circuitry 105. Local circuits A.n and B.n are electrically connected to interfacing circuitry 107. Local circuits C.n and D.n are electrically connected to interfacing circuitry 109.

Each local circuit (A.1-A.n, B.1-B.n, C.1-C.n, D.1-D.n) is connected to receive the control signal from the common control signal source 101. Additionally, the interfacing circuitry (103, 105, 107, 109) is connected to receive the control signal from the common control signal source 101. Electrical signal transitions in the gated paths of local circuits A.1, C.1, A.n, and C.n are initiated by the arrival of an electrical signal transition at control inputs of transistors in the respective gated paths. The gated paths of local circuits A.1, C.1, A.n, and C.n can include a number of transistors that drive electrical signals to the respective interfacing circuitry 103, 105, 107, and 109. For each of local circuits B.1, D.1, B.n, and D.n, upon arrival of the control signal at the local circuit from the control signal source 101, the electrical signal states held by the transistors within the setup paths of the local circuit will be released. The interfacing circuitry 103, 105, 107, and 109 to which the local circuits B.1, D.1, B.n, and D.n are respectively connected can drive one or more electrical signals into the setup paths of the local circuits to resolve the one or more electrical signal states within the setup paths prior to arrival of the control signal from the control signal source 101.

It should be understood that the control signal from the control signal source 101 can arrive at the various local circuits (A.1-A.n, B.1-B.n, C.1-C.n, D.1-D.n) and interfacing circuitry (103, 105, 107, 109) at different times depending on delays encountered by the control signal. The control signal delay may be caused by RC delay, buffers, intervening circuitry, distance, or any other signal delay inducing cause. With regard to the example of FIG. 1, the delay of the control signal at local circuits A.1 and B.1 is represented by delay 1. The delay of the control signal at local circuits C.1 and D.1 is represented by delay 2. The delay of the control signal at local circuits A.n and B.n is represented by delay 3. The delay of the control signal at local circuits C.n and D.n is represented by delay 4. The delay of the control signal at interfacing circuitry 103 is represented by delay 5. The delay of the control signal at interfacing circuitry 105 is represented by delay 6. The delay of the control signal at interfacing circuitry 107 is represented by delay 7. The delay of the control signal at interfacing circuitry 108 is represented by delay 8.

It should be understood that the delay of the control signal at a given local circuit will effect the timing margin of the gated paths or setup paths within the given local circuit. The methods disclosed herein identify local circuits that have excess timing margin in their gated paths and/or setup paths due to the delay of the control signal arrival at the local circuits, and determine how the excess timing margin may be consumed through biasing of transistors within the gated paths and/or setup paths of the identified local circuits in order to reduce power consumption of the biased transistors without compromising the integrity of the local circuit timing.

It should be appreciated that some transistors can afford to be designed slower, i.e., designed to have more delay, because they are in either a gated path or a setup path that has timing margin to spare. And, by designing a given transistor to be slower, it is possible to reduce power consumption and/or leakage by the given transistor. Therefore, when multiple transistors having excess timing margin are designed to be slower, the overall reduction in power consumption can be appreciable.

A bias candidate transistor within a local circuit refers to a transistor under investigation for design modification to determine whether or not the bias transistor can be designed slower to realize corresponding power savings without compromising signal timing integrity of the local circuit. Bias candidate transistors are generally not at extreme locations with respect to control signal origination. Also, bias candidate transistors are generally not defined in circuits that are responsible for timing, such as clocking circuits or control signal circuits. Bias candidate transistors within local circuits can be selected for design modification investigation in different ways. The following represents a number of possible embodiments, among others, by which bias candidate transistors can be identified:
In one embodiment, bias candidate transistors include the transistors within the critical gated/setup path in all instances of the local circuit type under consideration.
In another embodiment, bias candidate transistors include the transistors in only non-critical gate/setup paths in all instances of the local circuit type under consideration.
In another embodiment, bias candidate transistors include the transistors in both critical and non-critical gate/setup paths in only those instances of the local circuit type under consideration where a variation in global control signal delay can be made without changing the original worst case timing within the set of local circuits of the type under consideration.
In another embodiment, bias candidate transistors include only non-critical gate/setup paths in only those instances of the local circuit type under consideration where a variation in global control signal delay can be made without changing the worst case timing of the set of local circuits of the type under consideration.

Once bias candidate transistors are identified for evaluation, it is necessary to determine whether or not the identified bias candidate transistors can be biased slower without compromising the timing integrity of the local circuit. To ensure that the timing integrity of the local circuit is maintained, it is necessary to ensure that the timing margin of the local circuit following modification of the bias candidate transistors is positive.

The timing margin of the local circuit refers to a timing relationship between the local circuit and interfacing circuitry to which the local circuit is connected. As mentioned above, the timing margin of a given gated path in a local circuit is measured between a moment of arrival at the given gated path of the control signal, and a moment at which electrical signal transitions in the gated path must be initiated to ensure timely completion of those electrical signal transitions for proper operation of circuitry that interfaces with the given gated path, i.e., for proper operation of interfacing circuitry to which the local circuit is connected. Also, the timing margin of a given setup path in a local circuit is measured between a moment at which electrical signals within the given setup path resolve to the desired electrical signal states, and a moment of arrival at the given setup path of the control signal to effectively lock-in the electrical signals which should be resolved to the desired electrical signal states within the local circuit.

Timing margin in a given gated/setup path may exist for many different reasons. In one embodiment, timing margin in a given gated/setup path exists due to over-simplification of modeling of timing controlled circuits associated with the given gated/setup path. In another embodiment, timing margin in a given gated/setup path exists due to design assumptions, such as application of a worst case timing situation as a design criteria for all related timing controlled circuits, even when the worst case timing situation is not reasonably applicable to the given gated/setup path.

Additionally, the quantification of timing margin associated with a given gated/setup path can vary in complexity. In one embodiment, the timing margin of the local circuits along a timing controlled interface increases monotonically based on the control signal travel distance between the control signal source and the various local circuits. In this embodiment, the timing margin of a given gated path local circuit can be approximated by a difference between the maximum control signal delay of all the gated path local circuits and the control signal delay of the given gated path local circuit. For example, with reference to FIG. 1, in this embodiment the timing margin of the gated paths in local circuit A.1 would be approximated as delay 4 minus delay 1, assuming that local circuit C.n has the most delayed control signal from the control signal source 101. Also in this embodiment, the timing margin of a given setup path local circuit can be approximated as a difference between the minimum control signal delay of all the setup path local circuits and the control signal delay of the given setup path local circuit. For example, with reference to FIG. 1, the timing margin of the setup paths in local circuit D.n would be approximated as delay 4 minus delay 1, assuming that local circuit B.1 has the least delayed control signal from the control signal source 101.

In another embodiment, the control signal source supplies a control signal to both local circuits along the timing controlled interface and to interfacing circuitry along the timing controlled interface. In this embodiment, although the control signal transmitted to both local circuits and interfacing circuitry is from the same control signal source, there may be differences in delay of the control signals along the interface. For example, with reference to FIG. 1, delay 1 of the control signal arrival at local circuit B.1 may be different than delay 5 of the control signal arrival at interfacing circuitry 103. These differences in control signal delay along the timing controlled interface may either increase or decrease control signal timing margin at a given point along the timing controlled interface. Additionally, in some embodiments, intelligent control signal timing may be implemented along the timing controlled interface such that local circuitry and interfacing circuitry is not operated solely based on arrival of the control signal from the common control signal source. In these embodiments, the timing margin of a given local circuit will need to account for the intelligent control signal timing implementation to ensure that consumption of the timing margin in the given local circuit is acceptable.

Regardless of the reason for the timing margin existence, however, excess timing margin is not generally necessary for proper circuit timing and operation. Therefore, if excess timing margin exists in a given gated/setup path, that excess timing margin may allow for slower transistor implementation in the given gated/setup path to realize corresponding power savings associated with the slower transistor implementation.

To determine if bias candidate transistors in a given gated/setup path can be modified, i.e., slowed down, a difference in timing of the given gated/setup path with bias candidate transistor modification versus without bias candidate transistor modification should be less than the initial timing margin for the given gated/setup path prior to bias candidate transistor modification. In other words, a maximum delay caused by modification of bias candidate transistors in a given local circuit must be less than the minimum control signal margin of the given local circuit. In the embodiment in which the timing margin of a given local circuit is approximated by the control signal delay difference between the given local circuit and a limiting local circuit, the timing impact due to modification of the bias candidate transistors in the given local circuit should be less than the control signal delay difference.

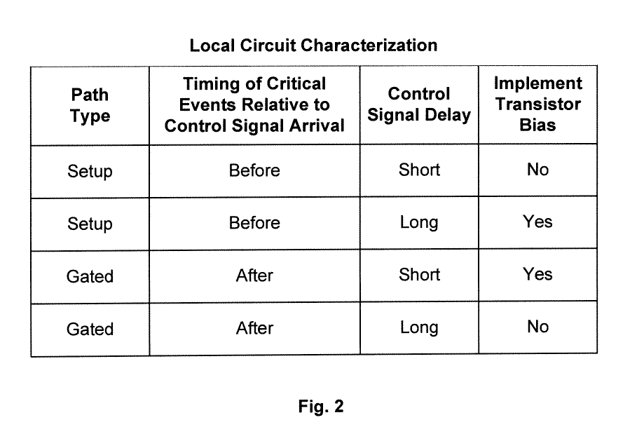

FIG. 2 shows a chart of local circuit characterization indicating whether or not bias candidate transistors of a local circuit should be modified, i.e., should be biased slower, in accordance with one embodiment of the present invention. The chart shows four conditions. In condition 1, the local circuit under consideration includes setup paths, such that the timing of critical events occurs before arrival of the control signal at the local circuit. Also in condition 1, the control signal delay at the local circuit is short. Therefore, in condition 1, the bias candidate transistors should not be modified to be slower. With reference to FIG. 1, local circuit B.1 represents condition 1, and its bias candidate transistors should not be modified.

In condition 2, the local circuit under consideration includes setup paths, such that the timing of critical events occurs before arrival of the control signal at the local circuit. Also in condition 2, the control signal delay at the local circuit is long. Therefore, in condition 2, the bias candidate transistors can be modified to be slower, thereby consuming less power and/or allowing lower leakage current. With reference to FIG. 1, local circuit D.n represents condition 2, and its bias candidate transistors can be modified.

In condition 3, the local circuit under consideration includes gated paths, such that the timing of critical events occurs after arrival of the control signal at the local circuit. Also in condition 3, the control signal delay at the local circuit is short. Therefore, in condition 3, the bias candidate transistors can be modified to be slower, thereby consuming less power and/or allowing lower leakage current. With reference to FIG. 1, local circuit A.1 represents condition 3, and its bias candidate transistors can be modified.

In condition 4, the local circuit under consideration includes gated paths, such that the timing of critical events occurs after arrival of the control signal at the local circuit. Also in condition 4, the control signal delay at the local circuit is long. Therefore, in condition 4, the bias candidate transistors should not be modified to be slower. With reference to FIG. 1, local circuit C.n represents condition 4, and its bias candidate transistors should not be modified.

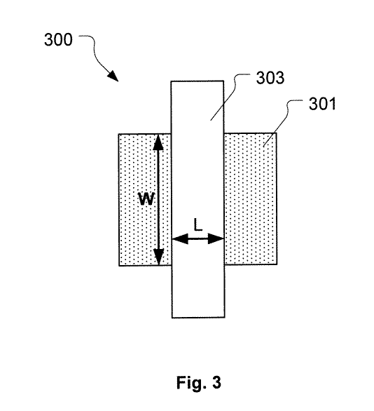

FIG. 3 shows a diagram of a transistor 300, in accordance with one embodiment of the present invention. The transistor 300 includes a diffusion region 301, which is a region of a base substrate within which impurities are introduced for the purpose of modifying the electrical properties of the base substrate. The diffusion region 301 may be formed as either an n-type or a p-type diffusion region. The transistor 300 also includes a gate electrode 303 defined to extend over the diffusion region 301. A portion of the gate electrode 303 above the diffusion region 301 represents a channel of the transistor 300, such that the channel of the transistor 300 is defined by a channel width W and a channel length L.

Once a determination is made that modification of the bias candidate transistors within a local circuit is acceptable given the timing margin of the local circuit, the following three techniques can be used to modify the bias candidate transistors to reduce their power consumption and/or leakage at the cost of increased operational delay within the local circuit:
Reduce Channel Width W: When the channel width W is reduced, the gate electrode 303 leakage is reduced and the input capacitance of the transistor 300 is lower, thereby reducing the active power (CV²f) of the transistor 300. In other words, with reduced channel width W, the transistor 300 can be switched using less power. Also, with reduced channel width W, the crowbar current (over path between power and ground) during transistor 300 switching is reduced. Therefore, reducing channel width W also reduces capacitive loading. Additionally, the leakage current will decrease linearly as the channel width W is reduced, because the cross-section (leakage path) over which minority carriers can leak gets smaller. The channel width W can be reduced by drawing it smaller initially in the circuit layout, or by applying an overlay to reduce the as-drawn channel width W in the layout, similar to power trim techniques.
Increase Channel Length L: Increasing the channel length L provides a non-linear reduction in leakage current. Therefore, if only leakage is of concern, it is possible to modify, i.e., increase, only the channel length L. The channel length L can be increased using an overlay, such as in application of a power trim technique. The channel length L increase overlay is distributed with the layout data, and essentially directs the channel length L to be increased as part of an optical proximity correction (OPC) process.
Increase Threshold Voltage Vt (Without Modifying either the Channel Width W or the Channel Length L): When the threshold voltage Vt is increased, the leakage current will decrease. In this modification technique, the dimensions of the transistor 300 remain unchanged, but the leakage current is decreased and the speed of the transistor 300 is decreased. The threshold voltage can also be increased using an overlay.

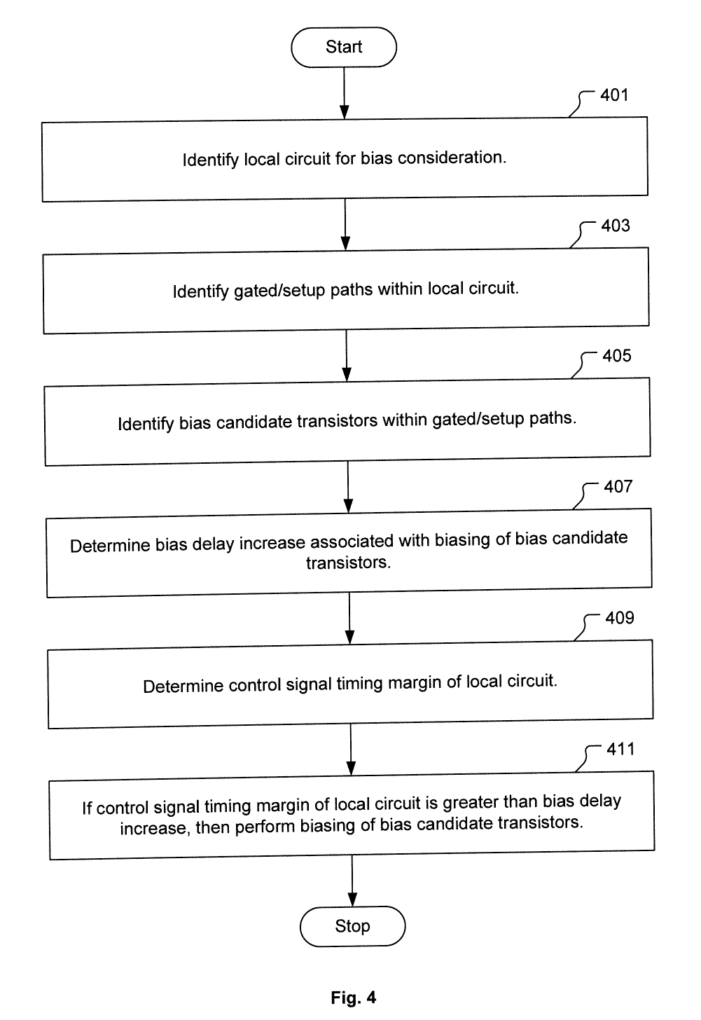

FIG. 4 shows a flowchart of a method for consumption of timing margin to reduce power utilization in an integrated circuit, in accordance with one embodiment of the present invention. The method includes an operation 401 for identifying a local circuit for bias consideration. More specifically, a local circuit along a timing controlled interface that operates in accordance with a common control signal is identified for bias consideration, wherein the bias consideration refers to potential biasing of transistors within the identified local circuit in order to trade off timing margin that may be present in exchange for reduced power utilization.

The method continues with an operation 403 to identify a gated path or a setup path within the identified local circuit. A gated path is an electrical signal path within the local circuit that is gated, i.e., operated, by transistors having respective control inputs connected to receive the common control signal. Electrical signal transitions in the gated path are initiated by the arrival of the common control signal at the respective control inputs of the transistors in the gated path. A setup path is an electrical signal path within the local circuit that includes transistors which together hold one or more electrical signal states that must respectively resolve to desired electrical signal states prior to arrival of the common control signal at one or more controlling transistors. Upon arrival of the common control signal, the one or more controlling transistors will activate to release the one or more electrical signal states held by the transistors within the setup path.

The method continues with an operation 405 to identify bias candidate transistors within the identified gated/setup paths. A bias candidate transistor within the local circuit refers to a transistor under investigation for design modification to determine whether or not the bias transistor can be designed slower to realize corresponding power savings without compromising signal timing integrity of the local circuit. An operation 407 is then performed to determine a bias delay increase associated with biasing of the identified bias candidate transistors. When each of the bias candidate transistors is biased, i.e., design modified, a speed of the bias candidate transistor is reduced in exchange for reduced power consumption and/or reduced leakage current associated with the bias candidate transistor. The bias delay increase determined in operation 407 represents the total amount of time that the local circuit is slowed down due to biasing/modification of the identified bias candidate transistors.

The method further includes an operation 409 to determine a control signal timing margin of the local circuit. The control signal timing margin of the local circuit represents the amount of time that exists between when the local circuit is ready for arrival of the common control signal and when the common control signal actually arrives at the local circuit. The timing margin of a local circuit based on a given gated path therein is measured between a moment of arrival at the given gated path of the common control signal and a moment at which electrical signal transitions in the gated path must be initiated to ensure timely completion of those electrical signal transitions for proper operation of circuitry that interfaces with the given gated path. The timing margin of a local circuit based on a given setup path therein is measured between a moment at which electrical signals within the given setup path resolve to the desired electrical signal states, and a moment of arrival at the given setup path of the common control signal.

The method proceeds with an operation 411 in which a determination is made as to whether or not the control signal timing margin of the local circuit is greater than the total bias delay increase due to biasing of the bias candidate transistors within the gated/setup paths within the local circuit. If the control signal timing margin of the local circuit is greater than the total bias delay increase of the local circuit, then the identified bias candidate transistors are tagged for biasing when the circuit is fabricated. If the control signal timing margin of the local circuit is not greater than the total bias delay increase of the local circuit, then the bias candidate transistors are not tagged for biasing, and the identified local circuit remains unchanged.

It should be understood that the method of FIG. 4 can be repeated as many times as necessary to fully evaluate any number of local circuits within an electronic device to be fabricated. Also, it should be appreciated that in one embodiment, the operations of the method of FIG. 4 can be performed automatically by a computer system operating in accordance with a correspondingly defined computer program. In this embodiment, the layouts of the integrated circuit can be provided in digital format as input to the computer system for processing. Also, in this embodiment, the computer system can be directed to automatically generate any necessary overlays or perform any necessary layout modifications as necessary to implement biasing of transistors as determined to be appropriate.

The delay biasing techniques disclosed herein can be applied to any circuit that has a data interface defined with a homogenous timing control, wherein the data interface controls data flow into and out of the circuit. The data interface in this case is a circuit domain that shares a timing control signal, and includes variation in timing control signal delay along the data interface. The present invention exploits this variation in timing control signal delay along the data interface to bias transistors, i.e., modify the design of the transistors, in order to reduce their power consumption and/or leakage current, at the expense of slowing down operation of the biased transistors, without compromising timing integrity along the data interface.

In one embodiment, the transistor biasing methods disclosed herein can be implemented in circuitry in which global control signals are used to trigger important events along a series of circuit banks, or periphery circuits within a circuit bank. In this embodiment, the global control signals may have substantial delay from their origination point to a most delayed arrival point within the circuitry. Also, in this embodiment, the series of circuit banks, or periphery circuits within the circuit bank, are not tuned based on their distance from the origination point of the global control signals. Also, in this embodiment, modeled setup and access time ranges of the series of circuit banks, or periphery circuits within the circuit bank, are not differentiated based on distance from the origination point of the global control signals. Additionally, it should be understood that the transistor biasing methods disclosed herein do not modify transistors in circuits that are responsible for timing, such as clocking circuits or control signal circuits. Also, the transistor biasing methods disclosed herein do not modify transistors in circuits that lack sufficient timing margin to support the transistor modifications.

In one embodiment, the number of circuit banks or periphery circuit transistors that can be safely biased in accordance with the method disclosed herein may be negligible if control signal delay variation is minimal. The sufficiency of variation in control signal delay can be evaluated as an early step in application of the method. In some cases, complier cell selection may become more complex. To offset this, the overlay post-compilation may be based on calculated power trim boundaries. Also, in some cases, memory characterization may become more complex. To offset this, a restriction can be implemented to ensure that modified cells are never responsible for worse case timing with a yes/no check for the particular MUX or as an extension to existing characterization simulations. It should be appreciated that the methods disclosed herein provide for reduced power consumption and/or leakage current through use of power trim style overlays without changing the block .lib file, without introducing risk, and without introducing excessive complication in terms of integrated circuit design, layout, compilation, and characterization.

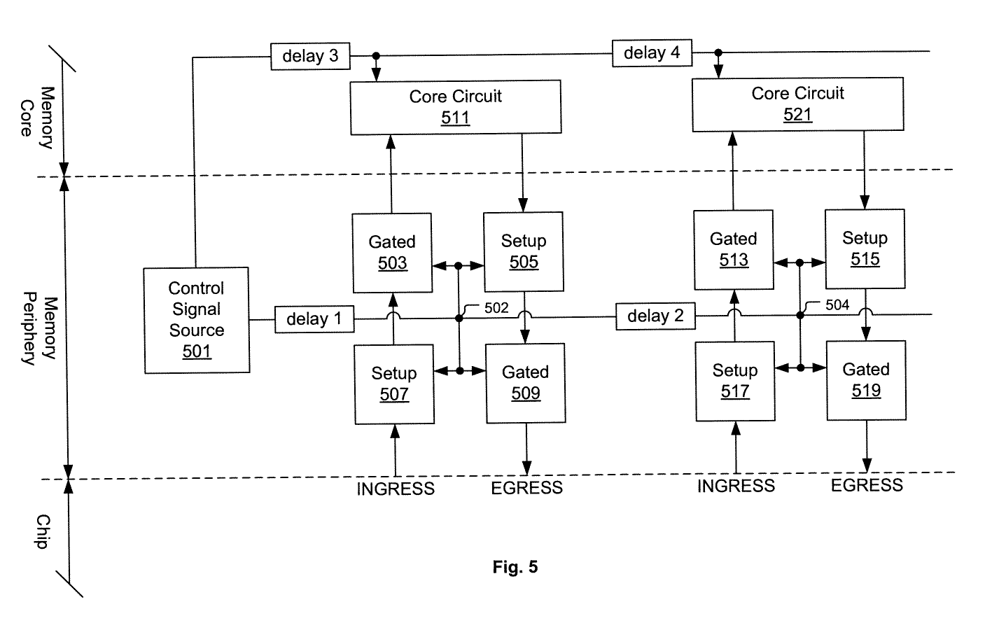

In one embodiment, the method for consumption of timing margin to reduce power utilization in an integrated circuit, as described above with regard to FIG. 4, is applied to a memory circuit. FIG. 5 shows a memory circuit architecture, in accordance with one embodiment of the present invention. The memory circuit architecture includes a memory periphery defined as a data interface between a chip and memory core. Both the memory periphery and the memory core include circuitry that operates in accordance with a common control signal generated by a control signal source 501. Along the interface within the memory periphery, the control signal source 501 transmits the common control signal to a first node 502 and a second node 504. The common control signal experiences a delay of delay 1 in its transmission to node 502. Similarly, the common control signal experiences a delay of delay 2 in its transmission to node 504. Also, the common control signal experiences delays of delay 3 and delay 4 in its transmission to core circuits 511 and 521, respectively. It should be appreciated that the delay of the common control signal at delay 2 is greater than at delay 1. Similarly, the delay of the common control signal at delay 4 is greater than at delay 3.

From the node 502, the control signal is transmitted to each of gated local circuit 503, setup local circuit 505, setup local circuit 507, and gated local circuit 509. The setup local circuit 507 and gated local circuit 503 define a data ingress path from the chip to the memory core circuit 511. The setup local circuit 505 and the gated local circuit 509 define a data egress path from the memory core circuit 511 to the chip. From the node 504, the control signal is transmitted to each of gated local circuit 513, setup local circuit 515, setup local circuit 517, and gated local circuit 519. The setup local circuit 517 and gated local circuit 513 define a data ingress path from the chip to the memory core circuit 521. The setup local circuit 515 and the gated local circuit 519 define a data egress path from the memory core circuit 521 to the chip.

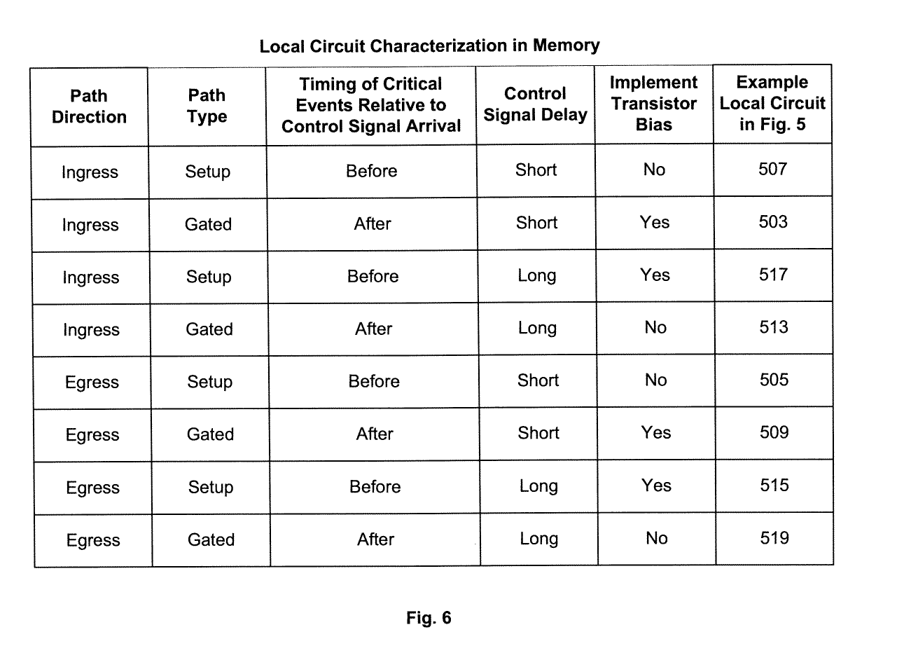

In the exemplary memory architecture of FIG. 5, there are eight situations that should be considered in determining whether or not bias candidate transistors within a given local circuit (503, 505, 507, 509, 513, 515, 517, 519) can be biased slower. FIG. 6 shows a chart of local circuit characterization in memory indicating whether or not bias candidate transistors of a local circuit in the data interface of the memory should be biased slower, in accordance with one embodiment of the present invention. As with the chart of FIG. 2, the decision to bias is based upon two primary criteria: 1) the path type, and 2) the control signal delay.

In setup paths, critical events must occur/complete before arrival of the control signal. In gated paths, critical events occur after arrival of the control signal. Bias candidate transistors within setup paths that have short control signal delay do not get biased. However, bias candidate transistors within setup paths that have long control signal delay can be biased. Bias candidate transistors within gated paths that have short control signal delay can be biased. However, bias candidate transistors within gated paths that have long control signal delay do not get biased. In the memory, local circuits that respectively include setup paths or gated paths are positioned based on the type of data path, i.e., ingress or egress, in which the local circuits are defined. Therefore, for clarity in FIG. 6, the local circuit biasing is further classified by the type of data path (ingress or egress) in which the local circuit is defined.

On the setup side of the ingress data path, such as in local circuits 507 and 517, it is necessary to get data signals resolved before the control signal arrives. For example, consider that the control signal is a latching signal that controls lock-in of the data at each bit. The data signals at the lesser delayed bits, e.g., local circuit 507, need to be ready faster than the data signals at the more delayed bits, e.g., local circuit 517, because the control signal will arrive at the lesser delayed bits sooner. Therefore, the more delayed bits have more timing margin with regard to getting the data signals ready before the control signal arrives to lock-in the data.

In one embodiment, the timing model (verilog or .lib) of the chip does not account for the difference in timing margin between the lesser delayed and more delayed bits with regard to the control signal arrival to latch-in data at the various bits. Therefore, in this embodiment, the timing for all bits with regard to the anticipated control signal arrival to latch-in data is based on the nearest bit, e.g., local circuit 507, which must be ready soonest. Consequently, the extra timing margin of the more delayed bits with regard to arrival of the input data latching control signal is available for consumption through biasing of bias candidate transistors in the local circuits which service the more delayed bits, in order to realize power savings in those biased transistors.

On the gated side of the ingress data path, such as in local circuits 503 and 513, the control signal arrival releases data for writing to the memory in core circuits 511 and 521. Thus, for the gated local circuits 503 and 513 on the ingress path, the control signal is a write control signal. The core cell of the memory (core circuit 511) that is less delayed with respect to arrival of the control signal will get updated earlier than the core cell of the memory (core circuit 521) that is more delayed with respect to arrival of the control signal. Therefore, depending on the available timing margin, it may be possible to slow the bias candidate transistors in the gated paths of the ingress path local circuits that have less control signal delay.

In one embodiment, the memory core is defined such that data ingress is allowed for a fixed period of time at each core cell, i.e., core circuit. In this embodiment, although the core cells that are less delayed with regard to the control signal may have more timing margin than the more delayed core cells, that timing margin is with respect to when the control signal arrives, and does not cover the time period set from control signal arrival to core cell closure at a given core cell. Therefore, although the core cells with less control signal delay have more timing margin for write operations than core cells with more control signal delay, there may be a cap on the timing margin for each core cell. So, in this embodiment, for a given core cell, it may be necessary to consider a control signal timing margin that is less than the control signal “arrival” timing difference between the given core cell and the most delayed core cell.

On the egress path, the control signal controls reading of bitlines and output of data from the memory. On the egress path, the bits having less delay in the control signal will provide read data more quickly. Therefore, the access time from the generation of the control signal to the availability of the data is slower for the more delayed bits. However, the timing model (verilog or .lib) in this application is simplified to say that all bits are the same in terms of control signal timing for read operations. So, there is no benefit from the fact that the bits having less control signal delay provide read data more quickly. Rather, the timing model across all bits is homogenized to the control signal timing of the most delay bit. Therefore, the chip timing model abstracts out the extra control signal timing margin in the lesser delayed bits so that the timing of all bits is based on the control signal timing of the most delayed bit. Therefore, depending on the available timing margin, it may be possible to slow the bias candidate transistors in the gated paths of the egress path local circuits (509) that have less control signal delay.

The ingress and egress paths may be going to other circuits that are timing controlled, and the timing of the other circuits may or may not be related to the timing of the control signal of the ingress/egress interface. In the memory, the timing of the core circuitry 511 and 521 in the memory core is related to the timing of the control signal along the ingress/egress interface in the memory periphery. In one embodiment, the control signal source supplies a control signal both along the data interface and a control signal within the memory core along the data interface. In this instance, although the control signal along in the data interface and within the memory core are from the same control source, there may be differences in delay of the control signals along the data interface in the memory core relative to the memory periphery. These differences in control signal delay may either increase or decrease control signal timing margin at a given point along the data interface.

For example, if the wordline delay is slower than the control signal delay, it may be possible to take advantage of timing margin. Consider that the wordline comes along very slowly, and the write driver is designed to start writing more quickly because the ingress/egress interface control signal has a smaller RC delay. In this case, it may be possible to delay some of the ingress/egress interface transistors because there is timing margin with respect to when the control signal on the wordline needs things to be ready along the ingress/egress interface.

Again, it should be noted that the method for consumption of timing margin to reduce power utilization in an integrated circuit, as disclosed herein, does not modify transistors in circuits that are responsible for timing, such as clocking circuits or control signal circuits. Also, the method does not modify transistors in circuits that lack sufficient timing margin For example, in applying the method to a memory circuit, the following types of circuits would not be modified: core circuits, self-timing-path circuits, including model core cells, internal clock generation circuits, or other control signal generation circuits.

It should be understood that the circuits and corresponding layouts generated by the methods disclosed herein can be stored in a tangible form, such as in a digital format in a layout data file on a computer readable medium. The layout data file can be formatted as a GDS II (Graphic Data System) database file, an OASIS (Open Artwork System Interchange Standard) database file, or any other type of data file format suitable for storing and communicating semiconductor device layouts.

Also, the methods disclosed herein can be embodied as computer readable code on a computer readable medium. The computer readable code can also include program instructions for performing the various operations of the methods disclosed herein. The computer readable medium can be any data storage device that can store data which can thereafter be read by a computer system. Examples of the computer readable medium include hard drives, network attached storage (NAS), read-only memory, random-access memory, CD-ROMs, CD-Rs, CD-RWs, magnetic tapes, and other optical and non-optical data storage devices. The computer readable medium can also be distributed over a network of coupled computer systems so that the computer readable code is stored and executed in a distributed fashion.

Any of the operations described herein that form part of the invention are useful machine operations. The invention also relates to a device or an apparatus for performing these operations. The apparatus may be specially constructed for the required purpose, such as a special purpose computer. When defined as a special purpose computer, the computer can also perform other processing, program execution or routines that are not part of the special purpose, while still being capable of operating for the special purpose. Alternatively, the operations may be processed by a general purpose computer selectively activated or configured by one or more computer programs stored in the computer memory, cache, or obtained over a network. When data is obtained over a network the data maybe processed by other computers on the network, e.g., a cloud of computing resources.

The embodiments of the present invention can also be defined as a machine that transforms data from one state to another state. The data may represent an article, that can be represented as an electronic signal and electronically manipulate data. The transformed data can, in some cases, be visually depicted on a display, representing the physical object that results from the transformation of data. The transformed data can be saved to storage generally, or in particular formats that enable the construction or depiction of a physical and tangible object. In some embodiments, the manipulation can be performed by a processor. In such an example, the processor thus transforms the data from one thing to another. Still further, the methods can be processed by one or more machines or processors that can be connected over a network. Each machine can transform data from one state or thing to another, and can also process data, save data to storage, transmit data over a network, display the result, or communicate the result to another machine.

It should be further understood that circuits and layouts that include transistors biased in accordance with the methods disclosed herein can be manufactured as part of a semiconductor device or chip. In the fabrication of semiconductor devices such as integrated circuits, memory cells, and the like, a series of manufacturing operations are performed to define features on a semiconductor wafer. The wafer includes integrated circuit devices in the form of multi-level structures defined on a silicon substrate. At a substrate level, transistor devices with diffusion regions are formed. In subsequent levels, interconnect metallization lines are patterned and electrically connected to the transistor devices to define a desired integrated circuit device. Also, patterned conductive layers are insulated from other conductive layers by dielectric materials.

While this invention has been described in terms of several embodiments, it will be appreciated that those skilled in the art upon reading the preceding specifications and studying the drawings will realize various alterations, additions, permutations and equivalents thereof. Therefore, it is intended that the present invention includes all such alterations, additions, permutations, and equivalents as fall within the true spirit and scope of the invention.

What is claimed is:

1. A semiconductor device, comprising:
a circuit defined to operate in accordance with a common control signal, wherein the circuit includes a plurality of transistors that have respective timing margins relative to the common control signal, wherein some of the plurality of transistors are differentiated from another of the plurality of transistors with regard to either transistor channel width, transistor channel length, transistor threshold voltage, or a combination thereof, and
wherein the differentiation of any given one of the plurality of transistors is defined to reduce either transistor power consumption, transistor current leakage, or a combination thereof, in exchange for a correspondingly reduced timing margin that remains positive.

2. A method for consumption of timing margin in an integrated circuit for reduce power utilization, comprising:
identifying a circuit defined to operate in accordance with a common control signal;
identifying a plurality of transistors within the circuit that have respective timing margins relative to the common control signal;
determining the respective timing margins of the plurality of transistors; and
defining some of the plurality of transistors differently from another of the plurality of transistors with regard to either transistor channel width, transistor channel length, transistor threshold voltage, or a combination thereof,
wherein the different definition of any given one of the plurality of transistors causes a reduction of either transistor power consumption, transistor current leakage, or a combination thereof, in exchange for a corresponding reduction in timing margin while maintaining a positive timing margin.
